(19) United States
(12) Patent Application Publication
(10) Pub. No.: US 2023/0092972 A1
(43) Pub. Date: Mar. 23, 2023

(54) DIMM COOLING ASSEMBLY WITH HEAT SPREADER ANTI-ROTATION MECHANISM

(71) Applicant: Intel Corporation, Santa Clara, CA (US)

(72) Inventors: Phil GENG, Washougal, WA (US); Guixiang TAN, Portland, OR (US); Yanbing SUN, Shanghai (CN); Xiang LI, Portland, OR (US); George VERGIS, Portland, OR (US); Sanjoy K. SAHA, Portland, OR (US)

(21) Appl. No.: 18/070,433

(22) Filed: Nov. 28, 2022

(30) Foreign Application Priority Data
Nov. 9, 2022 (CN) PCT/CN2022/130760

(51) Int. Cl. H05K 7/10; H05K 1/11; H01L 23/473; H05K 7/20; H05K 7/14

(52) U.S. Cl. CPC H05K 7/10; H05K 1/11; H01L 23/473; H05K 7/205; H05K 7/1402; H05K 2201/10159

(57) ABSTRACT

An apparatus is described. The apparatus includes a DIMM cooling assembly. The DIMM cooling assembly includes first and second heat spreaders to be respectively disposed on first and second sides of the DIMM's circuit board. The first and second sides having respective memory chips. The DIMM cooling assembly includes a heat dissipative structure. The DIMM's circuit board is to be disposed between the heat dissipative structure and a printed circuit board that the DIMM is to be plugged into. The DIMM cooling assembly includes fixturing elements to apply compressive forces toward the respective side edges of the DIMM's circuit board to the heat spreaders.

### RELATED APPLICATION

This application claims the benefit of priority to Patent Cooperation Treaty (PCT) Application No. PCT/CN2022/130760 filed Nov. 9, 2022. The entire content of that application is incorporated by reference.

### FIELD OF INVENTION

The field of invention pertains generally to the electrical arts, and, more specifically, to a DIMM cooling assembly with heat spreader anti-rotation mechanism.

### BACKGROUND

The continued reduction of transistor minimum feature size has resulted in tremendous numbers of transistors being integrated on a single logic chip. As a consequence, logic chip computational ability is reaching extremely high levels (e.g., as demonstrated by artificial intelligence implementations). Generally, logic chip computations use memory as a data scratch pad, data store and/or instruction store (for those logic chips that execute instructions in the case of the later). As logic chip computational ability continues to expand, the bandwidth and storage capacity of the memory used to support logic chip operation will likewise need to expand. The increase in memory performance likewise increases memory power dissipation which presents system engineering with memory chip cooling solution challenges.

### FIGURES

FIGS. 1a and 1b depict a prior art DIMM and cooling assembly;

FIGS. 2 and 3 show heat spreader rotation;

FIGS. 4, 5 and 6 show an improved DIMM and cooling assembly;

FIG. 7 shows a computing system.

### DETAILED DESCRIPTION

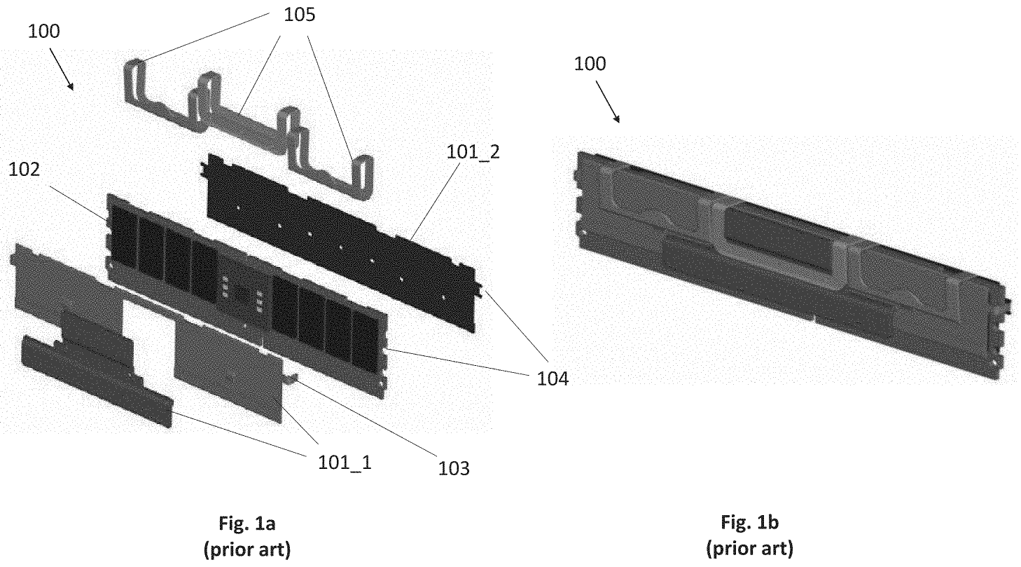

FIGS. 1a and 1b show a prior art dual in-line memory module (DIMM) 100 with heat spreaders 101_1, 101_2 (FIG. 1a shows an exploded view, FIG. 1b shows an assembled view). As observed in FIGS. 1a and 1b, semiconductor chips 102 (mainly memory chips) are mounted on both sides of the DIMM's circuit board. The semiconductor chips can generate large amounts of heat. As such, heat spreaders 101_1, 101_2 are placed on both sides of the DIMM. The front-side heat spreader 101_1 has a different shape than the back-side heat spreader 101_2 to account for the different chips and corresponding layouts on the sides of the DIMM's circuit board.

The flat, planar heat spreaders 101_1, 101_2, ideally, make flush contact with and press into the package lids of the semiconductor chips thereby creating a low thermal resistance path from the chip package lids to the heat spreaders 101_1, 101_2. The heat spreaders 101_1, 101_2 are composed of a thermally conductive material (e.g., a metal such as aluminum or copper).

With a low resistance thermal path between the chips and the heat spreaders 101_1, 101_2, heat generated by the chips is transferred to the heat spreaders 101_1, 101_2 with sufficient efficiency. The heat spreaders 101_1, 101_2 have a large surface area contact with the ambient that surrounds the DIMM 100, thus, heat is more efficiently transferred from the chips to the DIMM's ambient with the heat spreaders 101_1, 101_2 in place.

The heat spreaders 101_1, 101_2 are aligned to the DIMM 100 through the use of a tab 103 at the edge of one of the heat spreaders 101_1 that extends through a corresponding set of notches 104 in the DIMM circuit board and the other heat spreader 101_2. A set of such tabs and corresponding notches exist at both ends of the DIMM and, when engaged, effect lateral alignment of both heat spreaders 101_1, 101_2 and the DIMM circuit board.

As discussed above, ideally, the heat spreaders 101_1, 101_2 press into the package lids of the semiconductor chips to effect a low thermal resistance between the package lids and the heat spreaders. Here, C-shaped clips 105 are fitted over both heat spreaders 101_1, 101_2. The spring-like resistance of the clips 105 to being fitted over both heat spreaders 101_1, 101_2 presses the heat spreaders 101_1, 101_2 towards one another and into the package lids of the their respective DIMM sides.

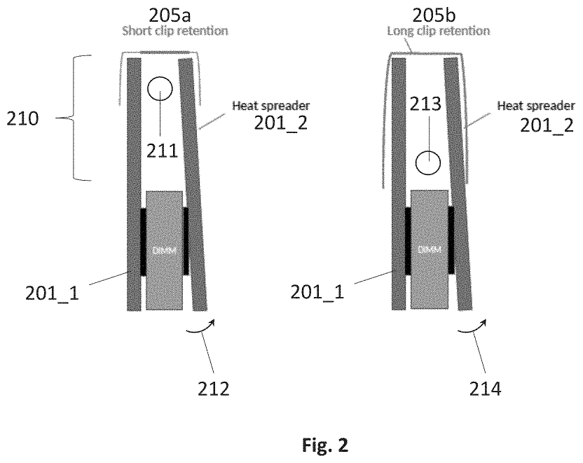

Referring to FIG. 2, the vertical height that a DIMM and its cooling assembly is allowed to consume has been expanded 210 to accommodate heat sink structures and/or liquid cooling structures in the space above the top of the DIMM (e.g., 1U+ racks).

Again, as with the prior art approach, one or more C shaped “clips” 205a, 205b can be used to press both heat spreaders 201 into their respective DIMM sides (FIG. 2a depicts both a short arm clip 205a and long arm clip 205b).

Unfortunately, when the arms of the clips 205a,b are placed over the heat spreaders and the C shaped spine of the clips 205a,b open outwardly, the expanded distance 210 of the heat spreaders and/or clip 205b can result in misalignment off the heat spreaders 201 on the DIMM and/or the DIMM within its DIMM socket. Specifically, the inward force exerted by the short arm clip 205a effects a higher axis of rotation 211 about which a heat spreader 201_2 can rotate away 212 from its package lid surfaces, whereas, the long arm clip 205b effects a lower axis of rotation 213 about which a heat spreader 201_2 can rotate away 214 from its package lid surfaces. The rotation 213, 214 results in air gaps between the heat spreader 201_2 and increased thermal resistance between the heat spreader 201_2 and the chip package lids it is supposed to press into.

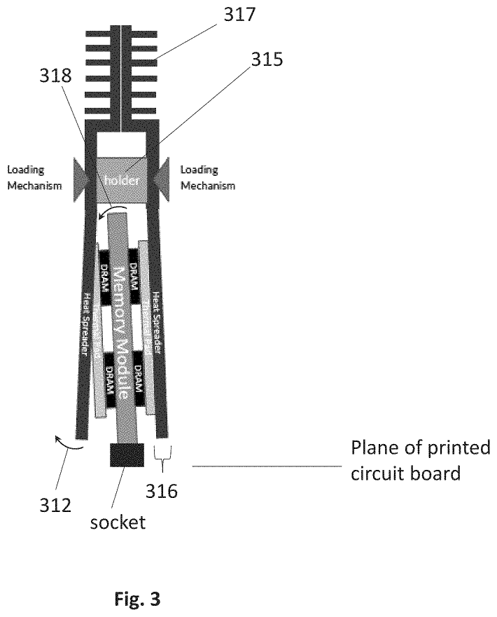

If a loading mechanism 315 is used instead of a retention clip, as observed in FIG. 3, the loading mechanism 315 (such as a screw that is threaded through both heat spreaders and tightened) applies inward forces to the heat spreaders and effects a similar axis of rotation that a heat spreader can rotate 312 about.

FIG. 3 also depicts more fully a newer generation cooling assembly that includes thicker 316 heat spreader material and additional heat transfer structure (heat sink structure 317) above the DIMM. Here, with the continued advancement of memory chip speed and memory chip storage cell density, memory chip power consumption and heat dissipation has increased in kind.

The thicker metal 316 heat spreaders further reduces the thermal resistance between the chip package lids and the heat spreaders (the heat spreaders have greater thermal mass and will therefore draw more heat from the semiconductor chip packages). Moreover, with the heat spreaders being mechanically integrated with the heat sink fins 317, the surface area contact of the overall structure with the ambient is increased which further improves heat transfer from the memory chips to the ambient.

Ideally the heat spreader structure 317 is centered along the vertical axis of the DIMM so that the weight of the heat spreader structure 317 and heat spreaders are distributed evenly on both sides of the DIMM.

Unfortunately, if a heat spreader rotates 312 when the loading mechanism 315 is tightened as described above, the rotation 312 can place the entire DIMM and heat spreader assembly out of balance. As a consequence, the DIMM can rotate 318 within its socket and create a bad electrical connection between the DIMM and the motherboard it is plugged into.

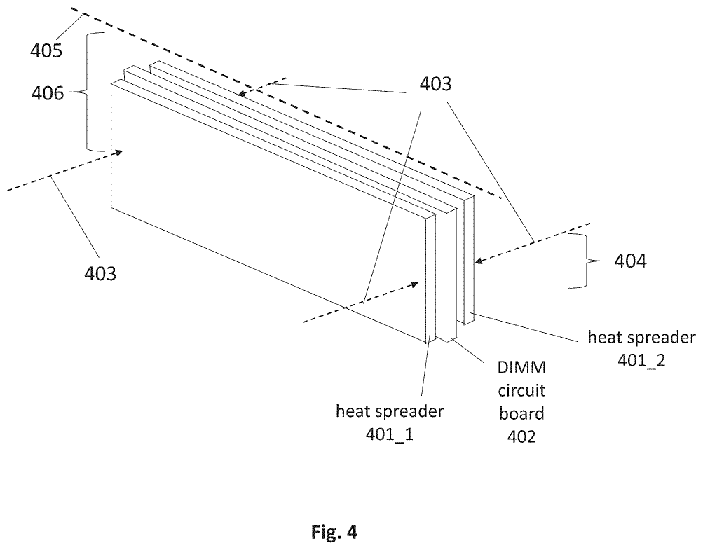

A solution, as observed into FIG. 4 is to apply some kind of compression force or blocking force 403 (hereinafter, “compressive force”) to the heat spreaders 401_1, 401_2 at one or both of the DIMM edges to substantially prevent the heat spreaders from rotating in a manner that creates air gaps between the heat spreaders 401_1, 401_2 and the corresponding chip package lids on the DIMM's circuit board 402.

Here, whereas the previously discussed solutions only created a compressive force above the DIMM's circuit board to press the heat spreaders into their respective DIMM sides, by contrast, the improved approach of FIG. 4 at least creates a compressive force 403 at or near the outer edges 406 of the DIMM. As described in more detail below, in various embodiments, compressive forces can also exist above the DIMM circuit board 402 as described at length above to help press the heat spreaders 401_1, 401_2 toward their respective sides of the DIMM (e.g., with a loading mechanism 315 as observed in FIG. 3, or with clips akin to the clips 105 of FIG. 1).

However, to the extent such a compressive force above the DIMM circuit board 402 induces either or both of the heat spreaders 401_1, 401_2 to rotate outward away from the DIMM circuit board 402, such inducement is largely nullified (e.g., blocked) by the presence of compressive force 403 mechanisms that are located at the DIMM edges. Notably, the compressive force is applied, e.g., approximately half way up 404 along the height of the DIMM circuit board 402 to apply a sufficient counteractive torque against heat spreader rotation about an axis 405 that exists above the DIMM circuit board 402. That is the, the distance 406 from the axis of rotation 405 above the DIMM circuit board 402 to the point of application of the compressive force 403 against the heat spreaders 401_1 401_2 creates a substantial lever arm that counter acts the rotation.

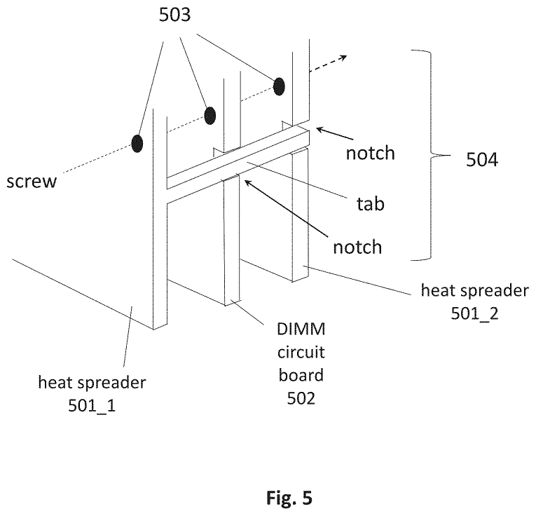

With respect to the precise compressive force mechanism, according to a first approach observed in FIG. 5, aligned through holes 503 are placed in both heat spreaders 501_1, 501_2 and the DIMM circuit board 502, e.g., near tab and notch alignment features that reside at both ends of the DIMM. A screw is inserted through the through holes 503 and tightened (e.g., the holes in the heat spreader opposite where the screw is inserted are threaded). The tightening of the screw draws the flat, planar regions of the heat spreaders 501_1, 501_2 towards one another which thwarts or otherwise diminishes any outward rotation force experienced by the heat spreaders 501_1, 501_2.

As alluded to above, the holes 503 are positioned at a low enough height 504 along the side of the DIMM circuit board 502 to create a substantial counter-torque to any outward rotational force experienced by the heat spreaders 501_1, 501_2. As such, in alternative embodiments, the holes 503 are not placed in immediate proximity of the lateral alignment tabs and notches (e.g., the holes 503 can be placed further down (to a lower height) along the DIMM edge).

In further embodiments, two or more sets of through holes are placed at each DIMM edge to effect an even greater compressive force 403 (e.g., at each DIMM edge that are two or more tightened screws to substantially prevent outward heat spreader rotation).

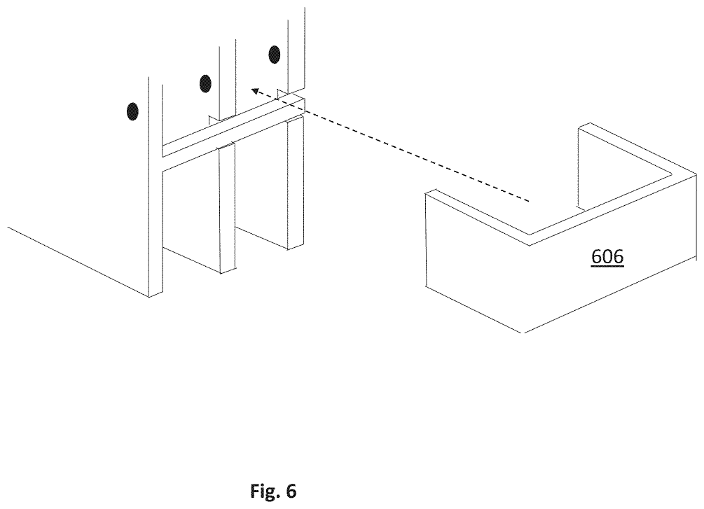

In alternative or combined approaches clips are placed at the DIMM edges. Such clips can be placed instead of, or in conjunction, with the aforementioned through holes and their corresponding screws. FIG. 6 shows a clip 606 being placed over the design of FIG. 5. Note that the width of the opening of the clip should be just large enough to snugly fit over both heat spreaders. In FIG. 6 this width is too wide because FIG. 6 shows an exploded view of the heat spreaders and DIMM circuit board, whereas, in practice they would be tightly coupled together with the tightened screw in the through holes and any other heat spreader attachment mechanism.

It is to be understood that the improvements described just above with respect to FIGS. 4, 5 and 6 can be applied to a new generation DIMM and DIMM cooling assembly (e.g., a 1U+) DIMM and cooling assembly having heat spreaders that include or are otherwise to be mechanically coupled to heat sink or other additional cooling features (e.g., heat pipes, fluidic cooling pipes, etc.) above the DIMM circuit board. FIG. 3 shows just one example of such a new generation DIMM and DIMM cooling assembly.

The improved DIMM cooling assembly described above can be integrated into various electronic systems such as a networking system (e.g., switch, router, etc.) or computing system.

The improved DIMM cooling assembly described above can be applied to various kinds of DIMMs including not only DIMMs that include dynamic random access memory (DRAM) memory chips but also DIMMs that include non-volatile, three-dimensional (monolithically stacked on a same memory die) memory cell memory chips (e.g., flash), as well as DIMMs that include non-volatile, three-dimensional, resistive storage cell, byte addressable memory chips (e.g., Optane™ memory from Intel corporation).

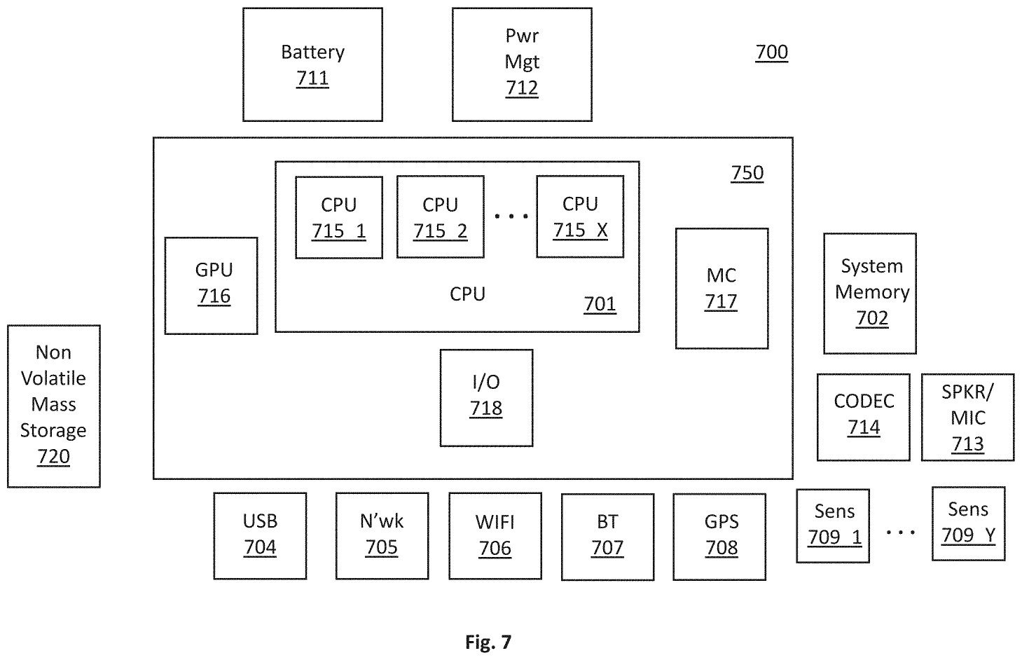

FIG. 7 depicts a basic computing system. The basic computing system 700 can include a central processing unit (CPU) 701 (which may include, e.g., a plurality of general purpose processing cores 715_1 through 715_X) and a main memory controller 717 disposed on a multi-core processor or applications processor, main memory 702 (also referred to as “system memory”), a display 703 (e.g., touchscreen, flat-panel), a local wired point-to-point link (e.g., universal serial bus (USB)) interface 704, a peripheral control hub (PCH) 718; various network I/O functions 705 (such as an Ethernet interface and/or cellular modem subsystem), a wireless local area network (e.g., WiFi) interface 706, a wireless point-to-point link (e.g., Bluetooth) interface 707 and a Global Positioning System interface 708, various sensors 709_1 through 709_Y, one or more cameras 710, a battery 711, a power management control unit 712, a speaker and microphone 713 and an audio coder/decoder 714.

An applications processor or multi-core processor 750 may include one or more general purpose processing cores 715 within its CPU 701, one or more graphical processing units 716, a main memory controller 717 and a peripheral control hub (PCH) 718 (also referred to as I/O controller and the like). The general purpose processing cores 715 typically execute the operating system and application software of the computing system. The graphics processing unit 716 typically executes graphics intensive functions to, e.g., generate graphics information that is presented on the display 703. The main memory controller 717 interfaces with the main memory 702 to write/read data to/from main memory 702. The power management control unit 712 generally controls the power consumption of the system 700. The peripheral control hub 718 manages communications between the computer's processors and memory and the I/O (peripheral) devices.

Other high performance functions such as computational accelerators, machine learning cores, inference engine cores, image processing cores, infrastructure processing unit (IPU) core, etc. can also be integrated into the computing system.

Each of the touchscreen display 703, the communication interfaces 704-707, the GPS interface 708, the sensors 709, the camera(s) 710, and the speaker/microphone codec 713, 714 all can be viewed as various forms of I/O (input and/or output) relative to the overall computing system including, where appropriate, an integrated peripheral device as well (e.g., the one or more cameras 710). Depending on implementation, various ones of these I/O components may be integrated on the applications processor/multi-core processor 750 or may be located off the die or outside the package of the applications processor/multi-core processor 750. The computing system also includes non-volatile mass storage 720 which may be the mass storage component of the system which may be composed of one or more non-volatile mass storage devices (e.g., hard disk drive, solid state drive, etc.). The non-volatile mass storage 720 may be implemented with any of solid state drives (SSDs), hard disk drive (HDDs), etc.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a DIMM cooling assembly comprising a), b) and c):
a) first and second heat spreaders to be respectively disposed on first and second sides of the DIMM's circuit board, the first and second sides having respective memory chips;
b) a heat dissipative structure, the DIMM's circuit board to be disposed between the heat dissipative structure and a printed circuit board that the DIMM is to be plugged into;
c) fixturing elements to apply compressive forces toward the respective side edges of the DIMM's circuit board to the heat spreaders.

2. The apparatus of claim 1 wherein the fixturing elements comprise aligned holes disposed in the first and second heat spreaders, the aligned holes to be aligned with holes disposed in the DIMM's circuit board.

3. The apparatus of claim 2 wherein screws are to be tightened within the aligned holes and the holes disposed in the DIMM's circuit board.

4. The apparatus of claim 2 wherein the fixturing elements further comprise clips that are to be applied at the respective side edges of the DIMM's circuit board.

5. The apparatus of claim 1 wherein the heat dissipative structure comprises heat sink fins.

6. The apparatus of claim 1 wherein the cooling assembly further comprises a loading force mechanism to be disposed between the heat dissipative structure and the DIMM's circuit board, the loading force mechanism to bring the first and second heat spreaders closer together with the DIMM's circuit board between the first and second heat spreaders.

7. The apparatus of claim 1 wherein the heat dissipative structure comprises a liquid cooling conduit.

8. An apparatus comprising:
a DIMM;
a DIMM cooling assembly that is mechanically coupled to the DIMM, the DIMM cooling assembly comprising a), b) and c):
a) first and second heat spreaders respectively disposed on first and second sides of the DIMM's circuit board, the first and second sides having respective memory chips;
b) a heat dissipative structure, the DIMM's circuit board disposed between the heat dissipative structure and a printed circuit board that the DIMM is to be plugged into;
c) fixturing elements that apply compressive forces toward the respective side edges of the DIMM's circuit board to the heat spreaders.

9. The apparatus of claim 8 wherein the fixturing elements comprise aligned holes disposed in the first and second heat spreaders, the aligned holes being aligned with holes disposed in the DIMM's circuit board.

10. The apparatus of claim 9 wherein screws are tightened within the aligned holes and the holes disposed in the DIMM's circuit board.

11. The apparatus of claim 9 wherein the fixturing elements further comprise clips that are applied at the respective side edges of the DIMM's circuit board.

12. The apparatus of claim 8 wherein the heat dissipative structure comprises heat sink fins.

13. The apparatus of claim 8 wherein the cooling assembly further comprises a loading force mechanism disposed between the heat dissipative structure and the DIMM's circuit board, the loading force mechanism bringing the first and second heat spreaders closer together with the DIMM's circuit board between the first and second heat spreaders.

14. The apparatus of claim 8 wherein the heat dissipative structure comprises a liquid cooling conduit.

15. An apparatus, comprising:
an electronic system comprising a DIMM plugged into a DIMM socket, the DIMM socket mounted to a printed circuit board, a cooling assembly being mechanically integrated with the DIMM, the cooling assembly comprising a), b) and c):
a) first and second heat spreaders respectively disposed on first and second sides of the DIMM's circuit board, the first and second sides having respective memory chips;
b) a heat dissipative structure, the DIMM's circuit board disposed between the heat dissipative structure and the DIMM socket;
c) fixturing elements that apply compressive forces toward the respective side edges of the DIMM's circuit board to the heat spreaders.

16. The apparatus of claim 15 wherein the fixturing elements comprise aligned holes disposed in the first and second heat spreaders, the aligned holes being aligned with holes disposed in the DIMM's circuit board, wherein, screws are tightened within the aligned holes and the holes disposed in the DIMM's circuit board.

17. The apparatus of claim 15 wherein the fixturing elements further comprise clips that are applied at the respective side edges of the DIMM's circuit board.

18. The apparatus of claim 15 wherein the heat dissipative structure comprises heat sink fins.

19. The apparatus of claim 15 wherein the cooling assembly further comprises a loading force mechanism disposed between the heat dissipative structure and the DIMM's circuit board, the loading force mechanism bringing the first and second heat spreaders closer together with the DIMM's circuit board between the first and second heat spreaders.

20. The apparatus of claim 15 wherein the heat dissipative structure comprises a liquid cooling conduit.
